(19) United States
(12) Patent Application Publication
(10) Pub. No.: US 2022/0294189 A1
(43) Pub. Date: Sep. 15, 2022

(54) MONOLITHICALLY INVERTED III-V LASER DIODE REALIZED USING BURIED TUNNEL JUNCTION

(71) Applicants: Cornell University, Ithaca, NY (US); INSTITUTE OF HIGH PRESSURE PHYSICS POLISH ACADEMY OF SCIENCES, 01-142- Warsaw (PL)

(72) Inventors: Henryk Turski, Warsaw (PL); Grzegorz MUZIOL, Warsaw (PL); Marcin SIEKACZ, Warsaw (PL); Czeslaw SKIERBISZEWSKI, Warsaw (PL); Debdeep Jena, Ithaca, NY (US); Huili Grace Xing, Ithaca, NY (US)

(21) Appl. No.: 17/601,058

(22) PCT Filed: Apr. 1, 2020
(86) PCT No.: PCT/US2020/026225

§ 371 Date: Oct. 2, 2021

Related U.S. Application Data
(60) Provisional application No. 62/829,126, filed on Apr. 4, 2019.

(51) Int. Cl. H01S 5/34; H01S 5/343; H01S 5/026

(52) U.S. Cl. CPC H01S 5/3416; H01S 5/34333; H01S 5/026; H01S 5/22

(57) ABSTRACT

Tunnel junctions (TJs) are used to invert a relative arrangement of the built-in polarization and current flow direction for metal (Ill)-polar grown Ill-nitride laser diodes (LDs). The resulting devices has subsequent TJ, p-type layers, active region and n-type layers. This arrangement ensures a band alignment which provides an injection efficiency of 100% without the need of close proximity of an electron blocking layer.

### CROSS-REFERENCE TO RELATED APPLICATIONS

This application claims priority to U.S. Provisional Patent Application No. 62/829,126, filed on Apr. 4, 2019, which is incorporated herein by reference in its entirety and for all purposes.

### BACKGROUND

Conventional Ill-nitride laser diodes grown on (0001) Ga-polar substrates are prepared by subsequent growth of n-type layers, active region and p-type layers. The reason for this sequence is to avoid presence of thick p-type layers due to their high resistivity. This arrangement causes a detrimental band alignment in the active region, arising from the built-in polarization in III-nitride heterostructures, which causes a decrease in the injection efficiency. This problem is partially solved by placement of a heavily Mg-doped (p-type) electron blocking layer near the active region. However, the Mg-doped layers are a cause of detrimental optical losses. Therefore, in the design of conventional laser diodes there is an interplay between the injection efficiency and optical losses.

### SUMMARY

The present technology is based on the use of tunnel junctions (TJs) to invert relative arrangement of the built-in polarization and current flow direction for metal (Ill)-polar grown III-nitride laser diodes (LDs). The device of theses teachings has subsequent TJ, p-type layers, active region and n-type layers. This arrangement ensures a band alignment which provides an injection efficiency of 100% without the need of close proximity of an electron blocking layer. This application is related to the previous invention titled “Platform enabled by buried tunnel junction for integrated photonic and electronic systems” (WIPO publication No. WO2019152611 of International Application No.: PCT/2019/015991, which is incorporated by reference herein in its entirety)

Both: LDs and light emitting diodes (LEDs) are light emitters. As such, monolithically inverted nitride LDs profit from the built-in field direction in similar way as LEDs described in the WIPO publication No. WO201915261 1 of International Application No.: PCT/2019/015991.

### BRIEF DESCRIPTION OF THE DRAWINGS

FIGS. 1A and IB show a schematic comparison between a laser diode of these teachings (FIG. 1A) and a conventional laser diode structure (FIG. IB);

FIGS. 2A, 2B and 2C show schematic pictorial representation of side view facing laser bar showing current (holes) flow for (a) monolithically inverted LD of these teachings (2A), (b) LD with tunnel junction used above active region (2B), and (c) typical laser diode with p-type layers on the top (2C);

FIGS. 3A, 3B, and 3C show schematic pictorial representations of an example laser structure of these teachings; and

FIGS. 4A and 4B show test results from an example laser structure of these teachings.

### DETAILED DESCRIPTION

The advantages, and other features of the systems and methods disclosed herein, will become more readily apparent to those having ordinary skill in the art from the following detailed description of certain exemplary embodiments taken in conjunction with the drawings which set forth representative embodiments of the subject technology.

Group III, as used herein, refers to CAS Group IIIA (Triels or the Boron group) in the periodic table.

Group V, as used herein, refers to the Nitrogen group.

Ill-nitride semiconductor materials, as used herein, refers to (Al, In, Ga and their alloys)N.

“Unintentionally doped,” as used herein, refers to material that is not doped other than unintentional impurities that are always introduced.

In Ill-nitride semiconductor heterostructures, built-in electronic polarization is present due to the lack of inversion symmetry in the wurtzite crystal structure. The metal (Ill)-polar p-down structures is ideal for LEDs and LDs because the p-n junction field and the polarization fields are aligned.

LDs operate at much higher current densities than LEDs: ˜1-2 kA/cm² for LDs vs 1-10 A/cm² for LEDs. For standard LEDs and LDs injection efficiency goes down with increasing current density. For LDs it finally freezes at lasing threshold. This means that for operating conditions LDs suffer more severely from the decrease in injection efficiency than LEDs. That is why adopting bottom TJ to the growth of Ga-polar nitride LD structure is extremely appealing.

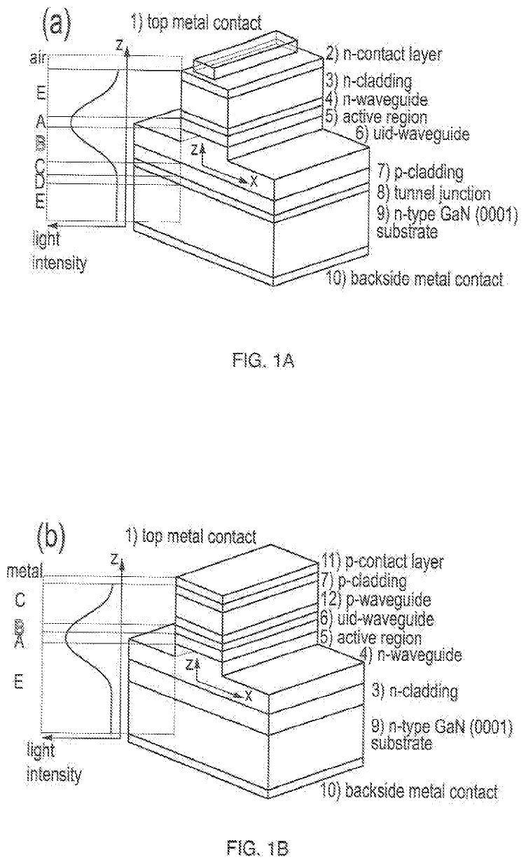

FIGS. 1A and IB show a schematic comparison between (a) the structure of a monolithically inverted laser diode of these teachings constructed using tunnel junction and (b) standard Ga-polar laser diode structure. On the left hand side, optical mode distribution and its overlap with corresponding layers is marked. A—active region, B—unintentionally/lightly doped layers, C—p-type layers, D—tunnel-j unction region, E—n-type layers.

In one or more implementations, the semiconductor laser structure of these teachings includes one or more layers of n doped Ill-nitride material disposed on a substrate, a tunnel junction disposed on the one or more layers of n doped Ill-nitride material, and a number of III-nitride material semiconductor layers formed on the tunnel junction, where at least one of the number of Ill-nitride material semiconductor layers formed on the tunnel junction forms an active region for lasing. In one implementation, the active region is deposited on a spacer layer, where the spacer layer can be an unintentionally doped Ill-nitride layer, a slightly p doped III-nitride layer or a slightly n doped III-nitride layer period. In some implementations, the spacer layer is disposed on the tunnel junction. In some implementations, the substrate is an n doped III-nitride material substrate. In some implementations, the one or more layers of n doped Ill-nitride material disposed on the substrate are a same n-doped Ill-nitride material as the substrate and can be considered part of the substrate.

In the implementation shown in FIG. 1A, a tunnel junction (8) is grown on an n-type GaN (001) substrate (9). A layer of p-doped Ill-nitride material (7) is grown on the tunnel junction (8). An unintentionally doped Ill-nitride material spacer layer (6) is grown on the layer of p-doped Ill-nitride material (7). The active region (5) is grown on the spacer layer-waveguide (6). A layer of n doped Ill-nitride material (4) is grown on the active region (5), followed by another layer of n doped Ill-nitride material (3), acting as cladding, grown on the layer of n doped Ill-nitride material (4).

For comparison, FIG. IB shows a typical Ga-polar laser diode structure. The typical laser diode structure is an upside down version of FIG. 1A. There are some additional layers in FIG. 1B, two other p doped Ill-nitride material layers (12, 11).

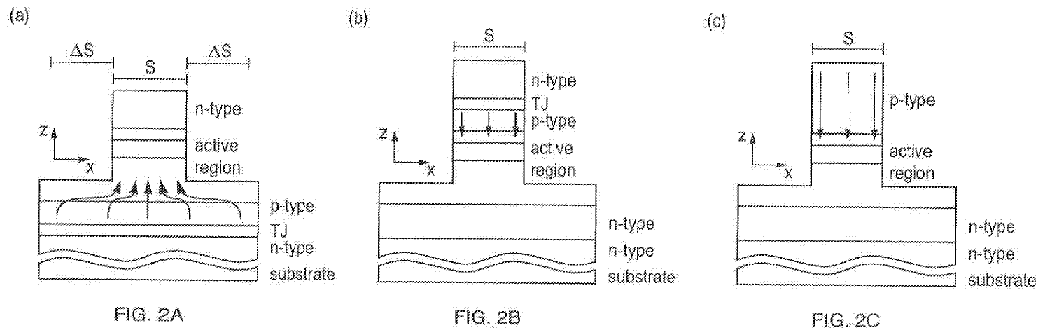

FIGS. 2A, 2B and 2C show schematic pictures of side view facing laser bar showing current (holes) flow for (a) monolithically inverted LD (2A), (b) LD with tunnel junction used above active region (2B), and (c) standard laser diode with p-type layers on the top (2C). Arrows indicate current (holes) flow direction and spreading close to p-type layers.

FIG. 2A shows how, if the mesa etching depth is selected such that area of the laser mesa (cross sectional area for a cross section in a plane perpendicular to a an axis normal to the substrate surface) is lager for a portion of the spacer layer 6 (as shown in FIG. 1A) or the p doped layer 7 than a cross sectional area of the active region and layers disposed on the active region, current spreading can be used effectively.

Bottom (buried) TJ is used to solve important limitations of a standard p-type up LDs grown on (0001) Ga-polar substrates that are:

Light losses due to absorption in p-type layers (region C in FIG. 1) that are close to the active region.

Decrease in carrier injection efficiency for high current density with increasing distance between active region and p-type layers.

Limited current spreading in the p-type layer that:

a. severely hampers the possibility of patterning the top surface of the laser mesa what is important for specific applications like distributed feedback LDs,
b. blocks the possibility of using top metal contact that covers only part of the mesa to use semiconductor/air interface as an efficient “air-cladding” to enhance light confinement in the waveguide.

Tunnel junction performance for TJ placed on top of the active region of the LD can increase the operation voltage of such device. Using inverted LD construction and defining laser mesa area (S in FIG. 2) by etching slightly below the active region enables the use of current spreading in the undoped or lightly doped layers below effectively increasing the area of the TJ to S+2AS.

This construction of III-V laser diode of the present teachings can be distinguished by the placement of tunnel junction below its active region. Such arrangement inverts the current flow with respect to polarization fields and the surface of laser diode heterostructure what opens new possibilities such as:

semiconductor/air interface can be used as an effective cladding to enhance light confinement,

much lower light absorption in the top most layer (E vs C in FIGS. 1A and IB) due to the change from n-type to p-type material,

good current spreading in n-type layers enables the patterning of top most layer for the use in devices like distributed feedback laser,

built-in polarization field aligned along junction p-n field enables high injection efficiency at high currents what is extremely important for laser diodes,

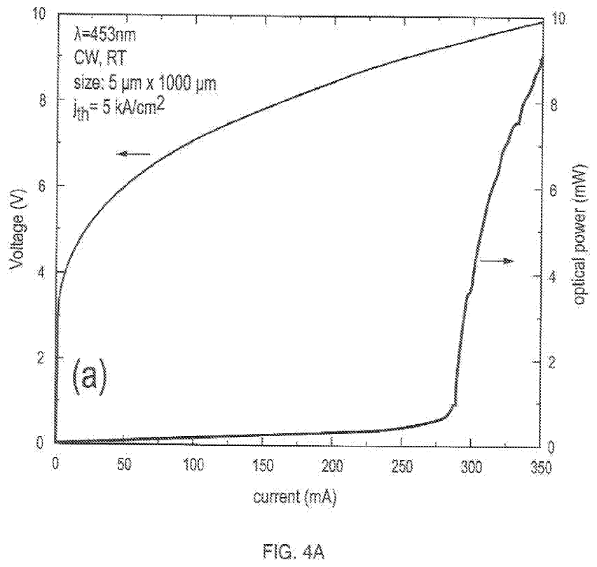

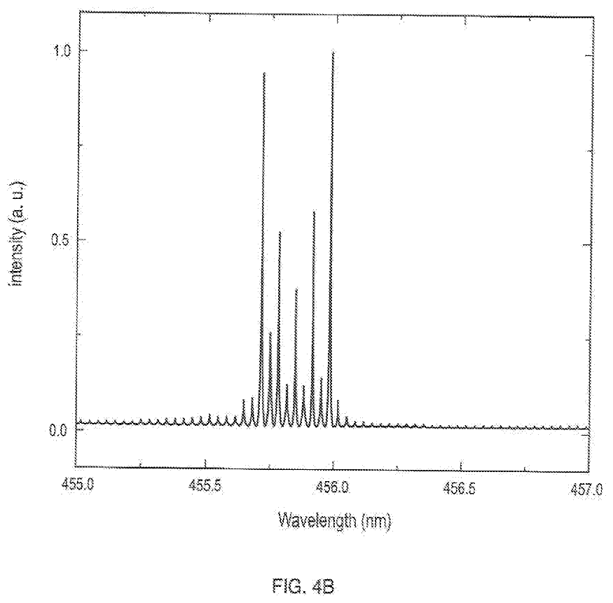

point d) opens possibility to put relatively thick spacer layer (B in FIG. 1A between active region (A) and p-type layers (C and D) that would be unintentionally doped or lightly doped for n- or p-type to separate optical mode in waveguide from p-type layers and by this to decrease light absorption losses (in FIG. 1A and FIG. 4A, active region 5 is deposited over a spacer layer 6, the spacer layer 6 being disposed between the active region 5 and the tunnel junction 8). For some implementations, using bottom-TJ geometry in a LD structure with a UID GaN spacer results in an enhancement in light output power of ˜30% in comparison to a standard top-TJ device.

improve tunnel junction performance by exploiting current spreading in the uid and/or p-type layers below active region (see arrows in FIG. 2A). Effective area of the tunnel junction is larger than the area of laser mesa (S+2AS vs S) leading to increased current at the same voltage bias.

The device of the present teachings can be made by molecular beam epitaxy (MBE), metal-organic vapor phase epitaxy (MOVPE) or other technique that is able to obtain nitride laser structures. Combining MBE and MOVPE or other techniques is also possible. The tunnel junction consists of highly doped n-type followed by highly doped p-type layer. On top of that laser diode structure can be grown using the same technique or other crystal growth method. The growth of laser diode starts with p-type layers which are followed by the active region and n-type layers.

In case of MBE growth there is no need of taking the crystal out of the reactor and the whole structure can be grown in a single growth process.

For MOVPE the main issue is to obtain conductive p-type layers that are overgrown with the laser structure. This problem can be addressed for example by activating p-type layers after the growth of p-type cladding layers (see layer 7) in FIG. 1A.), then capping it with thin unintentionally doped (uid) or n-type doped layers grown without H2. Such process will create a barrier that will block H2 from diffusing into the p-type layers and will enable the use of H2 during subsequent growth (keeping the buried p-type layers activated).

Typical mode of making the device is a single crystal growth process by either molecular beam epitaxy or metal organic vapor phase epitaxy to obtain laser nitride heterostructure. This way the time and cost of obtaining the structure is reduced.

After deposition, etching is used to define the mesa structure. The etching can be performed, for example, using inductively coupled plasma reactive ion etching (ICP-RIE).

In one or more implementations, the method of forming a semiconductor laser structure of these teachings includes growing, by a crystal growth method, a Ill-nitride material tunnel junction on a metal (Ill)-polar n-type Ill-nitride substrate, and growing, by the crystal growth method, a plurality of Ill-nitride material semiconductor layers formed on the tunnel junction, one or more of the plurality of Ill-nitride material semiconductor layers form an active region.

In order to present an example of these teachings, the structure presented in FIG. 4A was grown. In the example structure, no extended defects formed in tunnel junction allowing for high quality quantum well (QW) growth in the active region 5. A thick InGaN waveguide with an extra unintentionally doped GaN spacer 6 was used to exploit the lack of parasitic recombination observed in the work on bottom tunnel junction (BTJ) LEDs (see H. Turski et al., ECS J. of Sol. State Sci. and Tech. 9 (2020) 015018, which is incorporated by reference here in in its entirety and for all purposes). It should be noted that these teachings are not limited to this example.

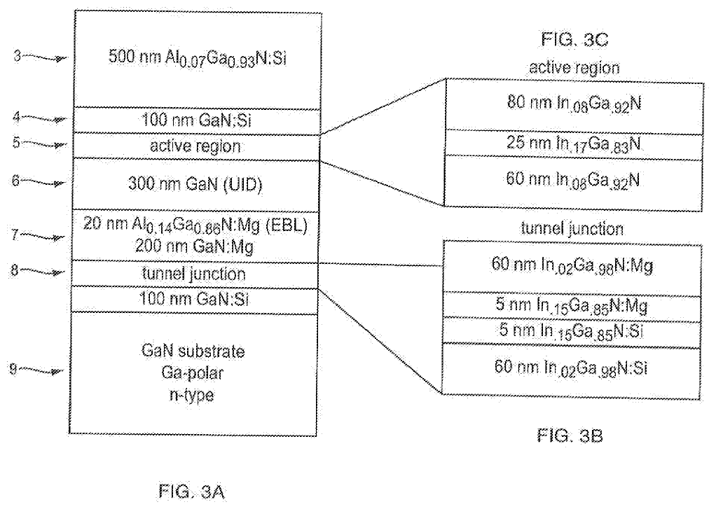

Referring to FIGS. 3A, 3B and 3C, in the example shown therein, the layers or regions are labeled with the same labeling as in FIG. 1A. FIGS. 3B and 3C provide more detail of the active region and of the tunnel junction. The doping concentrations are not indicated in those figures, but it should be noted that, in the tunnel junction, the 60 nm layers are heavily doped (have a higher doping concentration than layers such as the 100 nm GAN:Si layer that the tunnel junction is disposed on or the 200 nm GaN:Mg layer disposed on the tunnel junction) and the 5 nm layers are even more heavily doped. Tunnel junction 8 includes a very heavily doped p-type layer, the 5 nm Ino_{.15}Gao.85 N:Mg layer in the example, also referred to as a p++ layer, and a very heavily doped n-type layer, the 5 nm Ino_{.15}Gao.85 N:Si layer in the example, also referred to as an n++ layer.

It should also be noted that, in the example, the 20 nm AlGaN:Mg layer is more heavily doped than the 200 nm GaN:Mg layer disposed on the tunnel junction.

FIG. 3C provides more detail on the active region of the example. In the implementation shown in FIG. 3C, a single quantum well layer, the 25 nm Ino_{.17}Gao_{.83}N layer, is shown (a quantum well is realized with a thin layer of a semiconductor medium, embedded between other semiconductor layers of wider band gap). Although a single quantum well layer is shown in the example, multiple quantum well structures are also within the scope of these teachings.

FIGS. 4A and 4B show test results for the example laser structure of these teachings shown in FIGS. 3A, 3B and 3C. FIG. 4A shows the Light-current—voltage measured for the example monolithically inverted laser diode grown by PAMBE. Measurement was done at room temperature in continuous wave conditions. The curve of optical power versus current indicates the threshold current above which the optical power starts to increase more rapidly with current. The voltages corresponding to the currents at which the optical power is significant correspond to the “sufficient forward bias” applied to the active region, at which the active region lases. FIG. 4B shows the lasing spectra above threshold for the example monolithically inverted laser diode.

It should be noted that these teachings are not limited only to the example provided. Different layers of the structure can have significantly different thicknesses. In particular layer 6) and 7) in FIG. 1A can have thickness ranging from 0 to above 1 pm and different chemical compositions.

Doping of layers 6), 7) and 8) can be different than proposed above. For example:

layer 6) can be slightly n-type doped

layer 6) can be slightly p-type doped

layer 6) might not exist and layer 7) will act as a waveguide and cladding

layer 7) might not exist and p-type doping will occur only in tunnel junction—layer 8)

Mesa etching depth can be defined by different etching depths. In particular etching can be stopped in any layer located below or above the active region

Possible uses of the invention include but are not limited to:

Nitride based laser diodes,

Ultraviolet laser diodes,

Long wavelength laser diodes with low light losses

Distributed feedback laser diodes

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” “includes,” “including,” or any other variation thereof, are intended to cover a non-exclusive inclusion, such that a process, method, article, or apparatus that comprises or includes a list of elements or steps does not include only those elements or steps but may include other elements or steps not expressly listed or inherent to such process, method, article, or apparatus. An element preceded by “a” or “an” does not, without farther constraints, preclude the existence of additional identical elements in the process, method, article, or apparatus that comprises the element.

Unless otherwise stated, any and all measurements, values, ratings, positions, magnitudes, sizes, and other specifications that are set forth in this specification, including in the claims that follow, are approximate, not exact. Such amounts are intended to have a reasonable range that is consistent with the functions to which they relate and with what is customary in the art to which they pertain. For example, unless expressly stated otherwise, a parameter value or the like may vary by as much as plus or minus ten percent from the stated amount or range.

In addition, in the foregoing Detailed Description, it can be seen that various features are grouped together in various examples for the purpose of streamlining the disclosure. This method of disclosure is not to be interpreted as reflecting an intention that the claimed examples require more features than are expressly recited in each claim. Rather, as the following claims reflect, the subject matter to be protected lies in less than all features of any single disclosed example. Thus, the following claims are hereby incorporated into the Detailed Description, with each claim standing on its own as a separately claimed subject matter.

It will be appreciated by those of ordinary skill in the pertinent art that the functions of several elements may, in alternative embodiments, be carried out by fewer elements or a single element. Similarly, in some embodiments, any functional element may perform fewer, or different, operations than those described with respect to the illustrated embodiment. While the subject technology has been described with respect to preferred embodiments, those skilled in the art will readily appreciate that various changes and/or modifications can be made to the subject technology without departing from the spirit or scope of the subject technology.

What is claimed is:

1. A semiconductor laser structure comprising:
a substrate;
at least one layer of n doped Ill-nitride material disposed on said substrate;
a tunnel junction disposed on said at least one layer of n doped Ill-nitride material; and
a plurality of Ill-nitride material semiconductor layers formed on said tunnel junction; at least one of said plurality of Ill-nitride material semiconductor layers forms an active region;
wherein, upon application of a sufficient forward bias to said active region, said active region lases from a facet of the semiconductor laser structure.

2. The semiconductor laser structure of claim 1 wherein said active region is deposited over a spacer layer; said spacer layer being disposed between said active region and said tunnel junction.

3. The semiconductor laser structure of claim 2 wherein said spacer layer is at least one of an unintentionally doped Ill-nitride material or a lightly doped Ill-nitride material.

4. The semiconductor laser structure of claim 3 wherein said spacer layer is a layer of unintentionally doped Ill-nitride material.

5. The semiconductor laser structure of claim 3 wherein said spacer layer is a layer of slightly n doped Ill-nitride material.

6. The semiconductor laser structure of claim 3 wherein said spacer layer is a layer of slightly p doped Ill-nitride material.

7. The semiconductor laser structure of claim 2 wherein said spacer layer is disposed on the tunnel junction.

8. The semiconductor laser structure of claim 1 wherein said substrate is an n doped III-nitride material substrate.

9. The semiconductor laser structure of claim 8 wherein said at least one layer of n doped III-nitride material is a same n-doped Ill-nitride material as the substrate.

10. The semiconductor laser structure of claim 1 wherein said substrate is a metal (Ill)-polar n doped Ill-nitride material substrate.

11. A semiconductor laser structure comprising:
a substrate;
at least one layer of n doped Ill-nitride material disposed on said substrate;
a tunnel junction disposed on said at least one layer of n doped Ill-nitride material;
at least one layer of Ill-nitride semiconductor material; said at least one layer of Ill-nitride semiconductor material being one or more of at least one layer of p doped Ill-nitride material disposed on the tunnel junction or a spacer layer of Ill-nitride material;
an active region disposed on said at least one layer of Ill-nitride material; said active region comprising one or more layers of Ill-nitride material; and
at least one layer of n doped Ill-nitride material disposed on said active region;
wherein, upon application of a sufficient forward bias to said active region, said active region lases from a facet of the semiconductor laser structure.

12. The semiconductor laser structure of claim 11 wherein said spacer layer is at least one of an unintentionally doped Ill-nitride material or a lightly doped Ill-nitride material.

13. The semiconductor laser structure of claim 12 wherein said spacer layer is a layer of unintentionally doped Ill-nitride material.

14. The semiconductor laser structure of claim 11 wherein said spacer layer is disposed on the tunnel junction.

15. The semiconductor laser structure of claim 11 wherein said substrate is an n doped III-nitride material substrate.

16. The semiconductor laser structure of claim 15 wherein at least one layer of n doped III-nitride material disposed on said substrate is a same n-doped Ill-nitride material as the substrate.

17. The semiconductor laser structure of claim 11 wherein said substrate is a metal (Ill)-polar n doped Ill-nitride material substrate.

18. A method of forming a semiconductor laser structure, the method comprising:
growing, by a crystal growth method, a Ill-nitride material tunnel junction on a metal (III)-polar n-type Ill-nitride substrate;
growing, by the crystal growth method, a plurality of Ill-nitride material semiconductor layers formed on said tunnel junction; at least one of said plurality of Ill-nitride material semiconductor layers forms an active region.

19. The method of claim 18 wherein growing, by the crystal growth method, a III-nitride material tunnel junction on a metal (Ill)-polar n-type Ill-nitride substrate comprises:
growing, by the crystal growth method, at least one layer of n doped Ill-nitride material on the metal (Ill)-polar n-type Ill-nitride substrate; and
growing, by the crystal growth method, the Ill-nitride material tunnel junction on the at least one layer of n doped Ill-nitride material.

20. The method of claim 18 wherein said active region is grown, by the crystal growth method, over a spacer layer; said spacer layer being disposed between said active region and said tunnel junction.

21. The method of claim 20 wherein said spacer layer is grown on the tunnel junction.

22. The method of claim 20 wherein said spacer layer is grown on at least one layer of p doped Ill-nitride material; and
said at least one layer of p doped Ill-nitride material is grown, by the crystal growth method, on the tunnel junction.
